(19) United States
(12) Patent Application Publication
(10) Pub. No.: US 2007/0291462 A1
(43) Pub. Date: Dec. 20, 2007

(54) Apparatus For Suppressing EMI Generated In Differential High Frequency Data Transmission

(76) Inventor: Hsin Chih Peng, Hsinchu City (TW)

Correspondence Address: LIN & ASSOCIATES INTELLECTUAL PROPERTY, INC., P.O. BOX 2339, SARATOGA, CA, 95070-0339, US

(21) Appl. No.: 11/423,953

(22) Filed: Jun. 14, 2006

(51) Int. Cl. H05K 9/00

(52) U.S. Cl. 361/818

(57) ABSTRACT

An apparatus for suppressing EMI in the differential high frequency data transmission is provided, including the use of a plurality of closed-loops next to the transmission wires of data plus and data minus used in the differential transmission of data transmission bus of the flash memory pen, the EMI generated in the data transmission can be suppressed. When data is transmitted through the bus as electrical current, the magnetic field will be changed and the flux is also changed, which will induce an electrical field in the closed-loops, which will, in turn, induce a magnetic field. Therefore, the magnetic field generated by the closed-loops will annihilate the magnetic field generated by the data transmission; and hence the EMI is suppressed. Further more, the closed-loop of the present invention cab be designed as different shapes, such as circles, rectangular or others. In addition, the number of closed-loops can also vary.

### FIELD OF THE INVENTION

The present invention generally relates to an apparatus for high frequency data transmission, and more specifically to an apparatus for suppressing the electromagnetic interference (EMI) generated in differential high frequency data transmission.

### BACKGROUND OF THE INVENTION

As the computer and communication technologies progress rapidly, the processing power of CPU has continuously increased. Therefore, the data input/output capability of computer peripherals must also increase to match with the CPU processing power so that the data processed by the CPU can be transmitted through various networks, such as LAN or Internet, to other computers, servers or storage devices for further processing or storage.

On the other hand, the data transmission within a computer also require high speed transmission as the CPU must transmit processed data to a plurality of units within the computer, such as registers, buffers, ROM, RAM, flash memory, I/O devices, and so on, in addition to the peripherals connected to the computer. Therefore, the data transmission within the computer and with the peripherals must meet the data processing level of the CPU.

The differential high frequency data transmission is a promising technology that is developed to the demands. The differential high frequency data transmission is suitable for connecting to transformer or low-level signals. This technology is also applicable to computer data transmission technologies, such as the PCI bus of the peripherals having PCI_EXPRESS interface. PCI_EXPRESS is the current mainstream I/O technology of computers. When used, the differential transmission requires two transmission wires to transmit a bit, and these two transmission wires can only transmit in one direction, instead of both directions. That is, one transmission wire is Dp, and the other wire is Dm. Therefore, the signals of opposite phase are transmitted. These two wires are called a biration. According to the PCI_EXPRESS specification, each biration has a transmission speed of 2.5 Gbits/s. In actual application, it requires two birations for transmission, with one for upstream and the other for downstream. The advantages of PCI_EXPRESS include high scalability, high reliability, good upgradeability, and low manufacturing cost.

However, the electromagnetic interference (EMI) remains a problem in PCI_EXPRESS I/O technology. EMI not only interferes with the operations of the nearby electronic equipments, but also cause potential damages to the personnel working nearby. Therefore, it is imperative to reduce the EMI effect for the performance of electronic equipments as well as maintain the user's health.

For example, the flash memory pen using differential transmission technology may suffer from EMI. FIG. 1 shows a structure of a conventional flash memory pen using differential transmission technology. As shown in FIG. 1, a flash memory pen 10 includes a case 11, a NAND flash memory 12, a USB controller 13, a USB transmission wire 14, and an external USB connector 15. USB transmission wire 14 has the transmission speed of 480 MHz for USB2.0 specification. When the EMI test is conducted at the 960 MHz transmission speed from USB controller 13 directly to USB connector 15, the EMI value is about 30 dB, which is about 10 dB more than the CISPR CLASS-B 10 m CBL6112b-2563.

Refer to FIG. 2. FIG. 2 shows a schematic view of a flash memory pen having a mechanism for suppressing EMI. Most of the elements in FIG. 2 are similar to those in FIG. 1. A flash memory pen 20 of FIG. 2 further includes an additional common choke device 21, which is serially connected to the EMI source, the USB transmission wire 14. Common choke device 21 of FIG. 2 is structured as shown in FIG. 3, in which a flash memory pen 30 includes a USB transmission wire 34 serially connected to an inductor 35, a resistor 36 and a capacitor 37 in parallel. In addition, the printed circuit board further includes a case 31, a NAND flash memory 32, a USB controller 33, and an external USB connector 38. By connecting a common choke device having a 100 ohm resistance to the source of EMI (USB transmission wire 34), the generated magnetic field can annihilate the magnetic field generated by USB transmission wire. Therefore, the EMI in the flash memory pen be greatly reduced. However, the above has the disadvantage of being bulky in size because of the additional choke device, and additional manufacturing cost. Therefore, it imperative to further improve the EMI suppression or elimination devices.

### SUMMARY OF THE INVENTION

The present invention has been made to overcome the above-mentioned drawback of conventional EMI suppression or elimination devices. The primary object of the present invention is to provide an apparatus for suppressing the EMI generated in the differential high frequency data transmission, which can be manufactured during the printed circuit board (PCB) manufacturing process.

Another object of the present invention is to provide an apparatus for suppressing EMI in differential high frequency data transmission that is inexpensive in manufacturing and requires less circuit area and volume.

To achieve the above objects, the present invention provides an apparatus for suppressing EMI in the differential high frequency data transmission, including the use of a plurality of closed-loops next to the transmission wires of data plus (Dp) and data minus (Dm) used in the differential transmission of data transmission bus of the flash memory pen, the EMI generated in the data transmission can be suppressed. When data is transmitted through the bus as electrical current, the magnetic field will be changed and the flux is also changed, which will induce an electrical field in the closed-loops, which will, in turn, induce a magnetic field. Therefore, the magnetic field generated by the closed-loops will annihilate the magnetic field generated by the data transmission; and hence the EMI is suppressed.

Further more, the closed-loop of the present invention cab be designed as different shapes, such as circles, rectangular or others. In addition, the number of closed-loops can also vary.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic view of a conventional flash memory pen;

FIG. 2 shows a schematic view of a conventional flash memory pen with a mechanism for suppressing EMI;

FIG. 3 shows a circuit diagram of a conventional flash memory pen with a mechanism for suppressing EMI;

FIG. 4A shows a schematic view of a first embodiment of a flash memory pen with an apparatus for suppressing EMI according to the present invention;

FIG. 4B shows an enlarged view of the inset of the FIG. 4A;

FIG. 5A shows a schematic view of a second embodiment of a flash memory pen with an apparatus for suppressing EMI according to the present invention;

FIG. 5B shows a schematic view of a third embodiment of a flash memory pen with an apparatus for suppressing EMI according to the present invention;

FIG. 6 shows a cross-sectional view of the stacked layers formed by the closed-loop layers and insulation glass fiber layers according to the present invention; and

FIG. 7 shows a schematic view of a fourth embodiment of an apparatus for suppressing EMI according to the present invention.

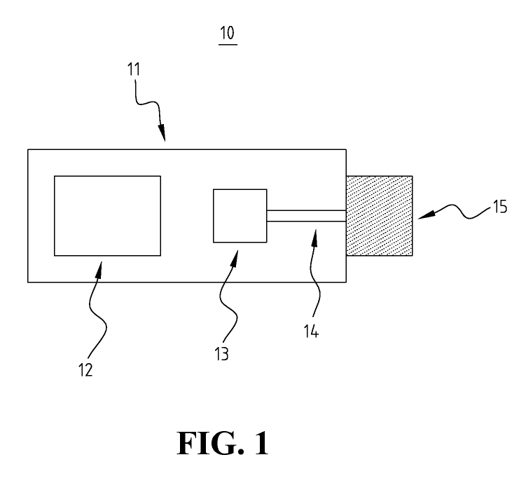

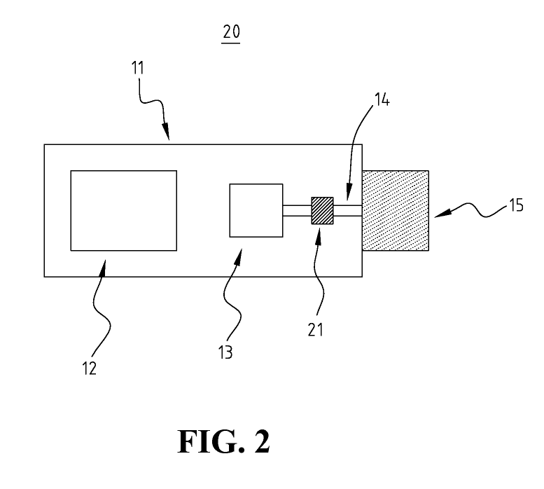

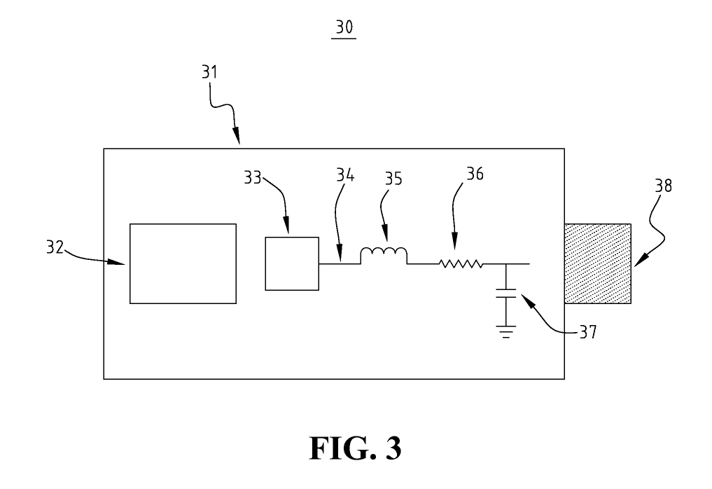

### DETAILED DESCRIPTION OF THE PREFERRED EMBODIMENTS

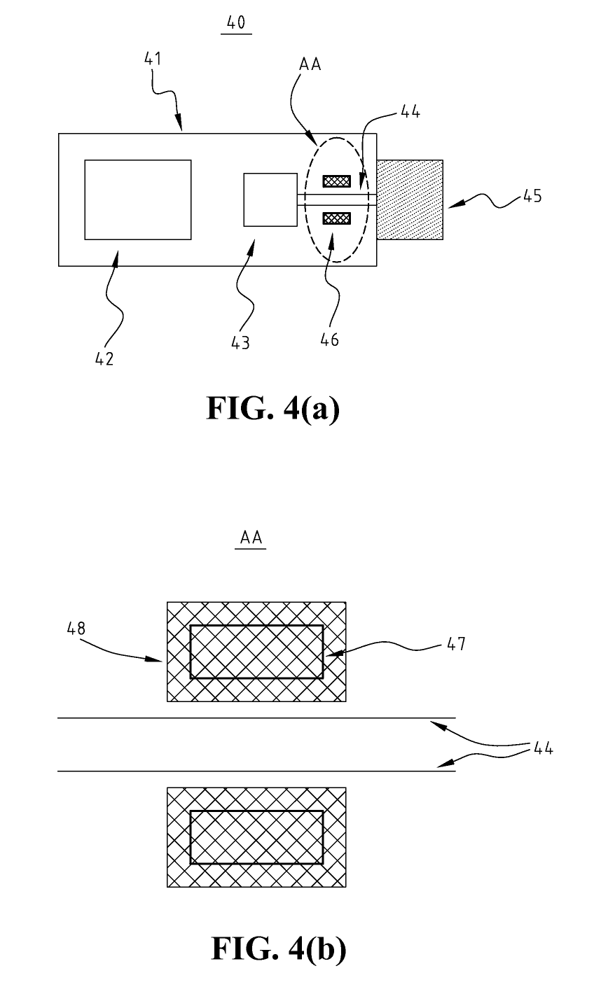

FIG. 4A shows a first embodiment of a flash memory pen having an apparatus for suppressing EMI according to the present invention. The embodiment shows the data transmission through bus of a flash memory pen. However, the present invention is not limited to the bus data transmission in a flash memory pen. Other equivalent applications using the differential data transmission technology is also within the scope the present invention. As shown in FIG. 4A, a flash memory pen 40 includes a case 41, a NAND flash memory 42, a USB controller 43, a USB transmission wire 44, at least a closed-loop 46, and an external USB connector 45. Closed-loop 46 may be made of a copper foil wire that can be manufactured during a PCB process. Closed-loops 46 are placed surrounding USB transmission wire 44. The shape of closed-loops 46 can vary, including circle, rectangular or others. The number of closed-loops can also vary. Closed-loops 46 further includes a closed-loop layer 47 and an insulation glass fiber layer 48, as the enlarged view shown in FIG. 4B. A thick rectangle in FIG. 4B is the closed-loop on closed-loop layer 47, and a rectangle with tiled-pattern is insulation glass fiber layer 48. Closed loop layer 47, insulation glass fiber layer 48, and USB transmission wire 44 are the remainders on the PCB after an etching process.

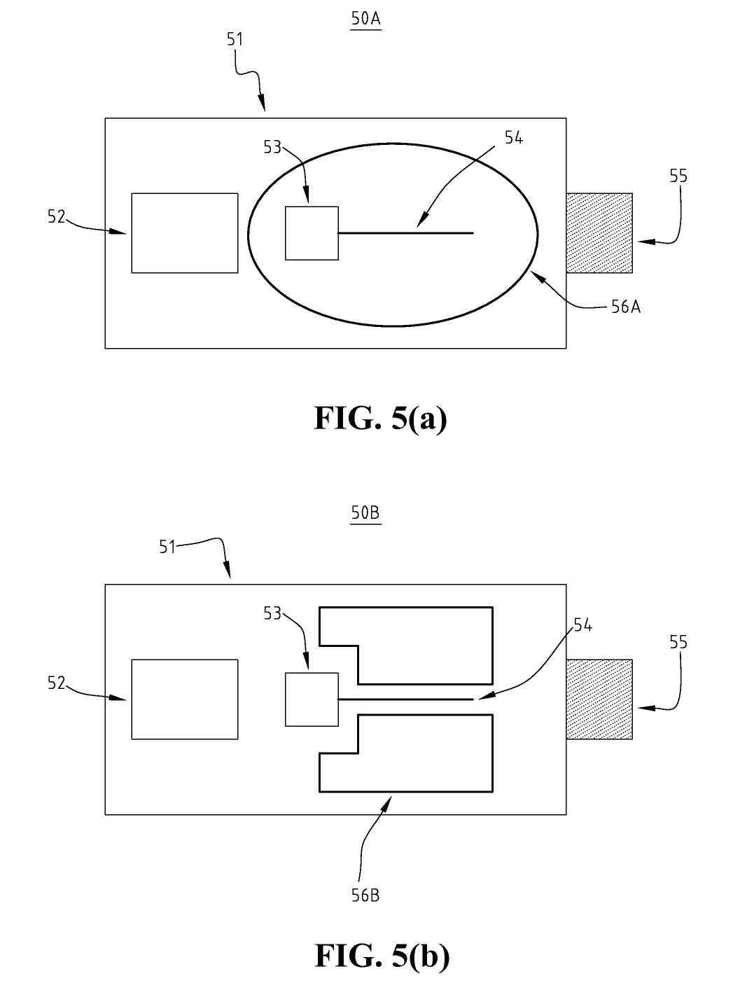

FIG. 5A and FIG. 5B show a second and a third embodiment of the present invention, respectively. As shown in FIG. 5A, a flash memory pen 50A includes a case 51, a NAND flash memory 52, a USB controller 53, a USB transmission wire 54, at least a closed-loop 56A, and an external USB connector 55. In FIG. 5A, closed-loop 56A is a circle that enclosing USB transmission wire 54. As shown in FIG. 5B, a flash memory pen 50B includes a case 51, a NAND flash memory 52, a USB controller 53, a USB transmission wire 54, at least a closed-loop 56B, and an external USB connector 55. In FIG. 5B, closed-loop 56B includes two rectangles with an extruding block on one side that sandwiching USB transmission wire 54.

When data is transmitted through the bus as electrical current, the magnetic field will be changed and the flux is also changed, which will induce an electrical field in the closed-loops, which will, in turn, induce a magnetic field. Therefore, the magnetic field generated by the closed-loops will annihilate the magnetic field generated by the data transmission; and hence the EMI is suppressed.

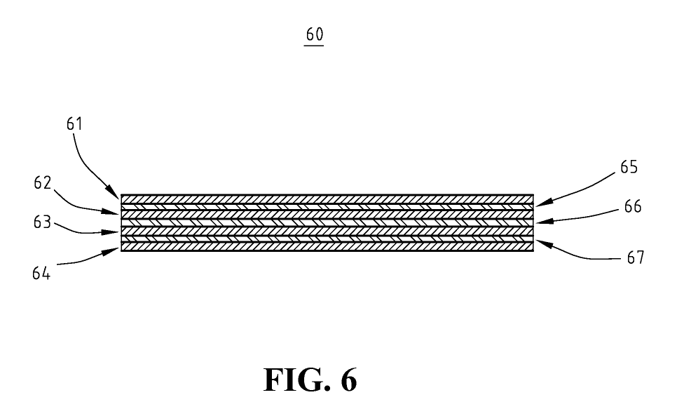

FIG. 6 shows a cross-sectional view of the interleaved closed-loop layers and insulation glass fiber layers. The number of the insulation glass fiber layers is one less than the number of the closed-loop layers. The embodiment shown in FIG. 6 includes four closed-loop layers and three insulation glass fiber layers, but any other numbers of layers are also within the scope of the present invention. The number of the layers depends on the strength of the EMI and the target EMI suppression level. As shown in FIG. 6, a stacked PCB layer structure 60 includes a first closed-loop layer 61, a second closed-loop layer 62, a third closed-loop layer 63, a closed-loop layer 64 interleaved by a first insulation glass fiber layer 65, a second insulation glass fiber layer 66, and a third insulation glass fiber layer 67. The PCB can be made of FPR4. In the above structure, each layer is neither grounded nor connected to Vcc.

The closed-loop layers are manufactured with the following process. The first step is to determine the shape of the wiring, i.e., the closed-loop. Then, the circuit is converted into a Geber file which will later made into a mask for exposure and etching, and the remaining circuit on the insulation glass fiber is the closed-loop. Finally, a plurality of layers is stacked to form the final closed-loop stack required for the design.

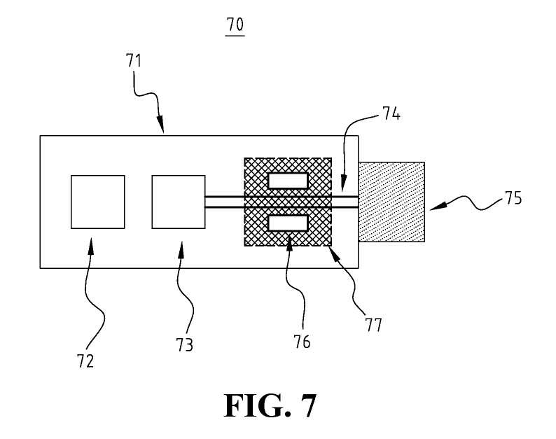

FIG. 7 shows a fourth embodiment of the present invention. A flash memory pen 70 includes a case 71, a NAND flash memory 72, a USB controller 73, a USB transmission wire 74, a closed-loop 76, an insulation glass fiber layer 77, and an external USB connector 75. In this embodiment, the data stored in NAND flash memory 72 is transmitted to a host (not shown) through USB transmission wire 74 and USB connector 75 under the control of USB controller 73. The EMI generated by the data transmission on USB transmission wire 74 is suppressed by magnetic field generated closed-loop 76.

Table 1 and Table 2 shows the measured results from the experiments Table 1 shows the EMI in a conventional flash memory pen with the data transmission at 480 MHz, 720 MHz, and 960 MHz, respectively. Table 2 shows the EMI in a flash memory pen having the closed-loop of the present invention with the data transmission at 480 MHz, 720 MHz, and 960 MHz, respectively. The third column of the tables shows the difference of measured EMI level and the standard level. As shown in Tables 1 and 2, with the closed-loop of the present invention, the flash memory pen suppresses much of the Emi at the high data transmission speed, i.e., 960 MHz.

TABLE 1

| | | | EMI | | | | |
|---|---|---|---|---|---|---|---|
| Trans- | EMI | | standard | | Pre- | | |
| mission | level | EMI | level | Sample | Amp | Antenna | Wire |
| Speed | (DbuV/ | exceeding | (DbuV/ | level | factor | Factor | loss |
| (MHz) | m) | level (dB) | m) | (DbuV) | (dB) | (dB/m) | (dB) |
| 480.08 | 33.62 | −3.38 | 37.00 | 41.67 | 28.22 | 17.63 | 2.54 |
| 720.64 | 29.86 | −7.14 | 37.00 | 35.12 | 28.56 | 19.90 | 3.40 |
| 960.23 | 48.36 | 11.36 | 37.00 | 50.80 | 27.98 | 21.24 | 4.29 |

TABLE 2

| | | | EMI | | | | |
|---|---|---|---|---|---|---|---|
| Trans- | EMI | | standard | | Pre- | | |
| mission | level | EMI | level | Sample | Amp | Antenna | Wire |
| Speed | (DbuV/ | exceeding | (DbuV/ | level | factor | Factor | loss |
| (MHz) | m) | level (dB) | m) | (DbuV) | (dB) | (dB/m) | (dB) |
| 480.08 | 33.20 | −3.80 | 37.00 | 41.25 | 28.22 | 17.63 | 2.54 |
| 720.64 | 32.83 | −4.17 | 37.00 | 38.09 | 28.56 | 19.90 | 3.40 |
| 960.23 | 36.09 | −0.91 | 37.00 | 38.53 | 27.98 | 21.24 | 4.29 |

It is worth noticing that the present invention is more effective when the data transmission speed is high, which, in general, will generate more EMI.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An apparatus for suppressing the electromagnetic interference (EMI) generated in differential high frequency data transmission, applicable to a device with a transmission wire for data to transmit on said transmission wire, said apparatus comprising a stacked structure, said stacked structure further comprising:
a plurality of insulation glass fiber layers; and
a plurality of closed-loop layers, form on said insulation glass fiber layers;
wherein the number of said closed-loop layers is equal to the number of said insulation glass fiber layers plus one, and said insulation glass fiber layers are interleaved with said closed-loop layers to form said stacked structure.

2. The apparatus as claimed in claim 1, wherein said closed-loop layer comprises at least a closed-loop circuit made of copper foil.

3. The apparatus as claimed in claim 2, wherein said closed-loop circuits are placed to surround said data transmission wire for suppressing EMI generated by data transmission on said data transmission wire.

4. The apparatus as claimed in claim 2, wherein the shape of said closed-loop circuit depends on the design of said data transmission wire.

5. The apparatus as claimed in claim 2, wherein the number of said closed-loop circuit depends on the design of said data transmission wire.

6. The apparatus as claimed in claim 1, wherein said numbers of said closed-loop layers and said insulation glass fiber layers depend on the target level of suppressed EMI.
